(19) United States
(12) Patent Application Publication
(10) Pub. No.: US 2017/0245394 A1
(43) Pub. Date: Aug. 24, 2017

(54) High Efficiency Heat Dissipation Methods And Systems For Electronic Circuits And Systems

(71) Applicant: Ironside Engineering Inc., Ottawa (CA)

(72) Inventors: Eric Matte, Ottawa (CA); Matthew Strentse, Ottawa (CA)

(21) Appl. No.: 15/436,501

(22) Filed: Feb. 17, 2017

Related U.S. Application Data
(60) Provisional application No. 62/296,647, filed on Feb. 18, 2016.

(51) Int. Cl. H05K 7/20

(52) U.S. Cl. CPC H05K 7/20409; H05K 7/20509

(57) ABSTRACT

A fluidic thermal exchange element adapted to cool a heat generating component includes a thermal conductive element having a first surface that thermally contacts the heat generating component and a second surface having fins in a cell configuration. A cover is fluidically sealed relative to the thermal conductive element to form a cavity and has first and second fluid access points arranged relative to the fins such that cooled fluid flowing from the first access point to the second access point in the cavity interacts with the fins and acquires thermal energy therefrom to create heated fluid at the second access point. A modular radiator receives the heated fluid from the second access point and cools the fluid to create the cooled fluid for recirculation to the first access point. The modular radiator has a plurality of fluid-fluid thermal coupling elements (FFTCEs), each including first and second fluid thermal interface elements disposed in a frame. A plurality of the FFTCEs are stacked upon each other between top and bottom plates to mechanically restrain the FFTCEs, and the top plate comprises a first fluid access port for accepting the heated fluid and directing the heated fluid to flow through access channels in the respective frames of the FFTCEs to provide heat exchange with the respective FFTCEs to provide the cooled fluid at a second fluid access port that is connected to the first fluid access point.

### CROSS-REFERENCE TO RELATED APPLICATIONS

This application claims priority to U.S. Provisional Patent Application Ser. No. 62/296,647, filed Feb. 18, 2016. The content of that application is herein incorporated by reference in its entirety.

### FIELD OF THE INVENTION

This invention relates to thermal management and more particularly to fluidic thermal exchange elements and fluid-fluid heat exchangers for devices, sub-systems, and systems within a range of industries.

### BACKGROUND OF THE INVENTION

Over the past 30-year time period (1984-2014) we have seen modern network communications and electronic technologies evolve from 140 Mb/s trunk links supporting desktop computer based users exploiting single core 20 MHz processors to global wavelength division multiplexed Tb/s links supporting discrete business and residential user data rates up to 1 Gb/s supporting 4 and 6 core 2-4 GHz desktop/server processors and 60 core 1 GHz server processors. At the same time mobile electronics and mobile data communications have evolved to the point where nearly three billion users representing approximately 40% of the global population exploit mobile devices for communications with communication speeds up to 150 Mb/s. At the same time many software driven activities such as gaming and computer aided design have evolved from discrete standalone applications to “online” multi-player and collaborative environments where users may simultaneously interact. All of this data routes through data centres that store and distribute the data on the Internet. In 2016 user traffic is expected to exceed 100 exabytes per month, or over 42,000 gigabytes per second. However, peak demand is considerably higher with projections of over 600 million users streaming Internet high-definition video simultaneously at peak times.

All of this data flowing into and out of these devices will generally be the result of data transfers between data centres and within data centres so that these overall IP traffic flows must, in reality, be multiplied many times to establish the total IP traffic flows. Each data centre comprises racks of electronics comprising data storage with big, fast hard drives and servers that take requests and move the data using fast switches to access the right hard drives and either write or read the data to the hard drives. Connected to these servers are routers that connect the servers to the Internet and therein the user and/or other data centres. In mid-2013 Microsoft stated it had itself over 1 million servers alone and Facebook™, see for example Farrington et al. in “Facebook's Data Centre Network Architecture” (IEEE Optical Interconnects Conference, 2013 available at http)://nathanfarrington.com/presentations/facebook-optics-oida13-slides.pptx), stated that the ratio between intra-data centre traffic to external traffic over the Internet based on a single simple request can reach 1000:1 and that typically 90% of the traffic inside data centres is intra-cluster.

At the same time as requiring an effective yet scalable way of interconnecting data centres and warehouse scale computers (WSCs), both internally and to each other, operators must provide a significant portion of data centre and WSC applications free of charge to users and consumers, e.g. Internet browsing, searching, etc. Accordingly, data centre operators must meet exponentially increasing demands for bandwidth without dramatically increasing the cost and power of the infrastructure. At the same time consumers' expectations of download/upload speeds and latency in accessing content provide additional pressure.

Historically microprocessor improvements from 1984-2004 were driven through increasing clock speeds as processor speeds increased from 20 MHz to 3 GHz. Subsequently processor speeds have typically maintained in the 2.5-4 GHz range and many microprocessor manufacturers have stated that circuit speeds are unlikely to exceed 5 GHz as both static and dynamic power dissipation considerably increase for deep sub-100 nm CMOS. Already, an Intel™ Core™ i7-5960X desktop processor with 8 cores operating up to 3.5 GHz with 20 MB cache consumes up to 140 W and an Intel™ Xeon Phi™ 7120X server coprocessor with 61 cores operating up to 1.2 GHz with 16 GB cache memory consumes 300 W. Such multi-core processors have therefore driven performance enhancements of the period 2004-2104. In some applications such as gaming “over-clocking” is employed to achieve increased processor performance although this does further increase power dissipation and may also require power supply upgrading. For example, the “standard” 3 GHz clock of the Intel™ i7-950 processor can be overclocked to 4.2 GHz representing a significant processing improvement. However, power consumption increases approximately 130 W from the “standard” 190 W to 320 W. Hence, a 40% processor speed increase results in 70% power consumption increase.

However, a server blade may in addition to the multi-core processor and the ancillary communications interfaces, power supply etc. necessary for the multi-core processor also support multiple hot-swappable storage devices such that an 80 W Intel™ Xeon E3 processor with a thermal design power rating of 80 W becomes an Intel™ S1200V3RP 1U server board supporting 8 hot swappable hard drives with dual 450 W redundant power supplies. With a standard 42U rack therefore 42 of these server boards can be installed dissipating up to 42×450 W=18,900 W. As a data centres can comprise 50,000 to 100,000 servers then there may be approximately 120 to 240 racks. At 240 racks at full rating then the overall power consumption is 240*18,900 W=4,536,000 W=4.536 MW.

Accordingly, system designers must address how to extract this heat initially from the packaging of the microprocessor and associated high speed memory etc. and then sequentially extract it efficiently from the card/board to the circuit pack (e.g. an encased server blade inserted into a rack), and then from the rack and the building.

Other aspects and features of the present invention will become apparent to those ordinarily skilled in the art upon review of the following description of specific embodiments of the invention in conjunction with the accompanying figures.

### SUMMARY OF THE INVENTION

It is an object of the present invention to address limitations within the prior art relating to fluidic thermal exchange elements and fluid-fluid heat exchangers for devices, sub-systems, and systems within a range of industries.

In accordance with an embodiment of the invention there is provided a fluidic thermal exchange element adapted to cool a heat generating component. The fluidic thermal exchange element includes a thermal conductive element having a first surface that thermally contacts the heat generating component and a second surface having fins in a cell configuration and a cover over the thermal conductive element that is fluidically sealed relative to the thermal conductive element to form a cavity. The cover has first and second fluid access points arranged relative to the fins such that cooled fluid flowing from the first access point to the second access point in the cavity interacts with the fins and acquires thermal energy therefrom to create heated fluid at the second access point. A modular radiator receives the heated fluid from the second access point and cools the fluid to create the cooled fluid for recirculation to the first access point. The radiator in an exemplary embodiment includes a plurality of fluid-fluid thermal coupling elements (FFTCEs), each FFTCE comprising first and second fluid thermal interface elements disposed in a frame. In exemplary embodiments of the radiator, a plurality of FFTCEs are stacked upon each other between top and bottom plates to mechanically restrain the FFTCEs. Also, the top plate includes a first fluid access port for accepting the heated fluid and directing the heated fluid to flow through access channels in the respective frames of the FFTCEs to provide heat exchange with the respective FFTCEs to provide the cooled fluid at a second fluid access port that is connected to the first fluid access point.

In exemplary embodiments, the fins comprise rows of slots that are aligned axially between the first and second fluidic access points. Alternatively, the fins may comprise a plurality of thermal interface projections disposed in one or more repetitive patterns whereby fluid flows through channels between the respective thermal interface projections from the first fluidic access point to the second fluidic access point. In further exemplary embodiments, the thermal interface projections are disposed in a staggered profile to provide increased fluid turbulence between the first and second fluidic access points. In such embodiments, the plurality of thermal interface projections may be arranged to repeatedly separate and combine sub-flows of the fluid to locally change the velocity of the fluid and to induce mixing of the sub-flows. Also, a plurality of cells of fins may be disposed on respective regions of the second surface of the thermal conductive element. In such embodiments, respective cells of fins may employ different materials and/or geometries within each cell.

In further exemplary embodiments, at least one of the FFTCEs includes the second thermal interface element combined with the frame in a single piece having an open recessed portion including a slot that accepts the first thermal interface element. In the exemplary embodiments, the first thermal interface element may have serpentine or linear folds. Also, the single piece may have a plurality of pins on a surface thereof. Also, in further exemplary embodiments, a plurality of stacks of the FFTCEs may be arranged in an array or in a three-dimensional configuration. One or more fans may be disposed with respect to respective sides of the radiator so as to move heat from the radiator. Alternatively, the radiator may be immersed in a cooling fluid. In still other exemplary embodiments, the FFTCEs may be arranged in the radiator to provide a first fluid flow and a second fluid flow that are one of co-directional, contra-directional, or at a predetermined non-zero angle relative to one another. Also, the FFTCEs may be arranges such that FFTCEs closer to the first fluid access port have a higher fin density or higher fluid flow therethrough compared to FFTCEs closer to the second access port. Also, a density of the first and second fluid thermal interface elements may vary along a length of the radiator due to variations in thermal transfer arising from varying temperature of the fluid circulating within the radiator

Alternate embodiments may also have a plurality of Fluid Thermal Exchange Elements, a plurality of Fluid-Fluid Heat Exchangers, a plurality of Fluid-Movers, and the related linkages, connections, and a plurality of Thermal Transport Fluids. Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts a fluidic thermal exchange element (FTEXE) employing a straight groove profile heatsink according to an embodiment of the invention;

FIG. 2 depicts a FTEXE employing a thermal interface projection (TIP) profile heatsink with straight profile according to an embodiment of the invention;

FIG. 3 depicts a FTEXE block employing a straight TIP profile heatsink with staggered profile according to an embodiment of the invention;

FIG. 4 depicts a FTEXE employing a single path large area heatsink according to an embodiment of the invention;

FIG. 5 depicts a FTEX block employing multiple single path heatsinks according to an embodiment of the invention;

FIG. 6 depicts FTEXE configurations for single and multiple path heatsinks according to embodiments of the invention;

FIGS. 7 and 8 depict a fluid-fluid heat exchanger (FF-HEX) exploiting modular design methodology according to an embodiment of the invention;

FIG. 9 depicts the fluid-fluid heat exchanger according to FIGS. 7 and 8 in exploded perspective view;

FIG. 10 depicts the fluid flow within the fluid-fluid heat exchanger of FIGS. 7 to 9 according to an embodiment of the invention;

FIG. 11A depicts perspective views of an individual unit cell according to an embodiment of the invention which forming the basis of the modular design (FF-HEX) depicted in FIGS. 7 to 10 respectively;

FIG. 11B depicts alternate geometries for fluid-fluid heat exchanger elements within the modular individual unit cell depicted in FIGS. 9, 12, and 14 respectively;

FIG. 12A depicts an exploded perspective view of an alternate individual unit cell according to an embodiment of the invention to that depicted in FIG. 11;

FIG. 12B depicts the fluid flows present within an individual unit cell according to an embodiment of the invention to that depicted in FIG. 11;

FIG. 13 depicts a fluid-fluid heat exchanger according to the modular design methodology according to an embodiment of the invention with alternate fluid flow within the modular unit cells;

FIG. 14 depicts the fluid flow within the fluid-fluid heat exchanger of FIG. 13 according to an embodiment of the invention;

FIG. 15 depicts an exploded perspective view of an individual unit cell according to an embodiment of the invention which employed within the modular design fluid-fluid heat exchanger depicted in FIG. 14;

FIG. 16 depicts a perspective view of a single piece individual unit cell according to an embodiment of the invention which may be employed within the modular design fluid-fluid heat exchanger depicted in FIG. 14;

FIG. 17 depicts elevation views of the single piece individual unit cell depicted in FIG. 16;

FIG. 18 depicts perspective bottom and cross-sectional views of the single piece individual unit cell depicted in FIG. 16;

FIG. 19 depicts a labelled view of an embodiment for purposes of establishing conventions used to describe alternate embodiments of the Apparatus; and

FIG. 20 depicts thermal energy extracted versus temperature difference for fluid-fluid heat exchangers according to embodiments of the invention.

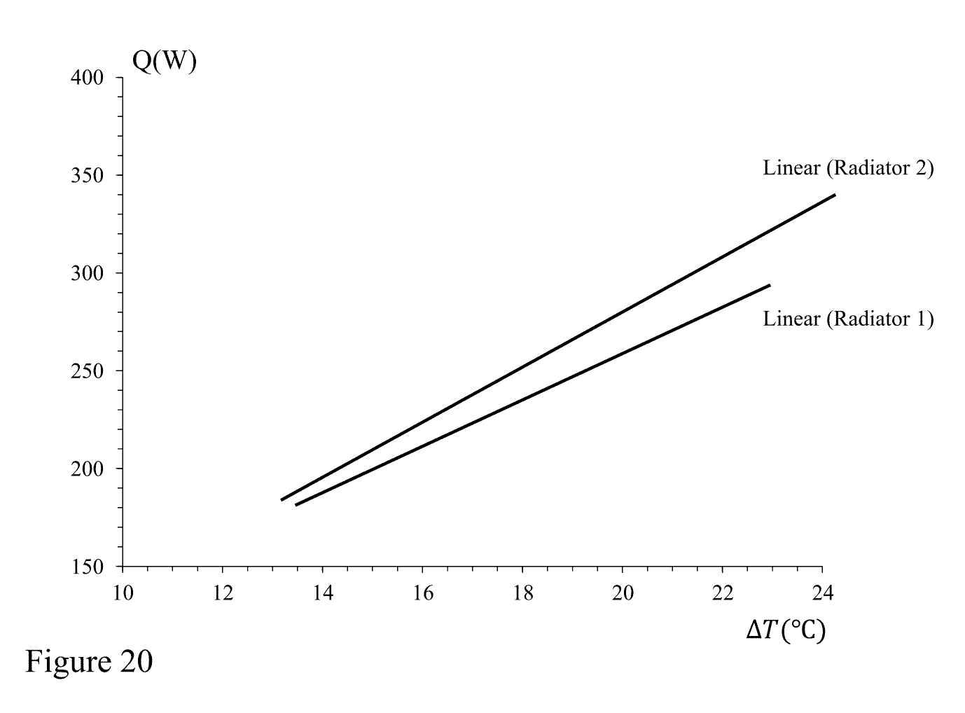

### DETAILED DESCRIPTION OF EXEMPLARY EMBODIMENTS

The present invention is directed to fluidic thermal exchange elements and fluid-fluid heat exchangers for devices, sub-systems, and systems within a range of industries.

The ensuing description provides representative embodiment(s) only, and is not intended to limit the scope, applicability or configuration of the disclosure. Rather, the ensuing description of the embodiment(s) will provide those skilled in the art with an enabling description for implementing an embodiment or embodiments of the invention. It being understood that various changes can be made in the function and arrangement of elements without departing from the spirit and scope as set forth in the appended claims. Accordingly, an embodiment is an example or implementation of the inventions and not the sole implementation. Various appearances of “alternate embodiments”, “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments. The definition and descriptive usage of a “preferred embodiment” or “exemplary embodiment” are illustrative and select from many design, implementation, manufacturing, and usage choices to provide disclosure herein. Embodiments of the disclosed Apparatus may use, combine, or replace conventional elements with unique and novel additions disclosed in order to solve technological limitations or meet requirements in extant systems and methods.

Reference in the specification to “alternate embodiments”, “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purpose only. When used the term “Apparatus” is understood to mean the range of possible embodiments disclosed that many be created from the unique and novel additions herein. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users. Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional element.

A “microprocessor” or “central processor unit” (CPU) as used herein and throughout this disclosure, refers to electronic circuitry within an electronic component, electronic device, electronic system etc. that carries out the instructions of a computer program by performing the basic arithmetic, logical, control and input/output (I/O) operations specified by the instructions. As such the term “CPU” refers to a processor, more specifically to its processing unit and control unit (CU), distinguishing these core elements from external components such as memory and Input/Output. Today most CPUs are microprocessors, meaning that they are contained on a single integrated circuit (IC) chip that may also contain memory, peripheral interfaces, and other components of a computer; such integrated devices are variously called microcontrollers or systems on a chip (SoC). Some CPUs employ a multi-core processor, which is a single chip containing two or more CPUs called “cores” wherein in that context, single chips are sometimes referred to as “sockets”. Array processors or vector processors have multiple processors that operate in parallel, with no unit considered central.

A “graphical processor unit” (GPU), also occasionally called visual processing unit (VPU), as used herein and throughout this disclosure, refers to a specialized electronic circuit designed to rapidly manipulate and alter memory to accelerate the creation of images in a frame buffer intended for output to a display. GPUs are typically used in embedded systems, mobile phones, personal computers, workstations, and gaming consoles. Modern GPUs are very efficient at manipulating computer graphics and image processing, and their highly parallel structure makes them more effective than general-purpose CPUs for algorithms where the processing of large blocks of visual data is done in parallel. In a personal computer, a GPU can be present on a video card, or it can be embedded on the motherboard or in certain CPUs on the CPU die.

A “fluid thermal exchange block” (FTEXE) as used herein and throughout this disclosure, refers to a heat sink or heat source exploiting fluidic extraction/provision of thermal energy to a device, circuit, element, etc. to which it is thermally connected with. A FTEXE is a passive heat exchanger that transfers heat generated by or required by an electronic, chemical, electro-chemical, mechanical, or electro-mechanical device and/or system. Within fluidic extraction a coolant fluid in motion (the thermal transport fluid) through the FTEXE the transferred heat leaves the device with the coolant fluid in motion, therefore allowing the regulation of the device temperature at physically feasible levels. In computers, FTEXEs are used to cool CPUs, GPUs, memory devices, etc. FTEXEs are used with high-power semiconductor devices such as power transistors, microwave mixers, microwave amplifiers, etc. and optoelectronics such as lasers and light emitting diodes (LEDs), where the heat dissipation ability of the basic device is insufficient to moderate its temperature.

Within fluidic provisioning a heating fluid in motion through the FTEXE thermal energy enters the device and removed from the heating fluid in motion that leaves cooler than at entry thereby allowing regulation of the devices temperate at levels physically infeasible to the device with at all or during initial operation. For example, fuel cells may require pre-heating prior to operation and generation subsequently of sufficient thermal energy to sustain operation. FTEXEs may also be employed in association with other generators of heat including, but not limited, fuel cells, electric vehicles, computer servers, server racks, microturbines, etc. or with other requires of heat such as chemical reactors, for example. FTEXEs may also be employed as part of thermal management solutions wherein in conjunction with a cooling system, e.g. a vapour-compression refrigeration unit, a gas absorption refrigeration unit, or liquefied gas, to reduce a device, component, assembly, etc. to below room temperature. FTEXEs may also be employed in conjunction with thermoelectric (Peltier) elements. FTEXEs may also be employed as part of thermal management solutions wherein in conjunction with a heating system they can be used to increase a device, component, assembly, etc. to higher temperatures than the inherent power dissipated by the device, component, assembly, etc. can reach.

A FTEXE is typically designed to maximize its surface area in contact with the fluid medium surrounding it. Fluid velocity, choice of fluid material, protrusion design, variance in materials, surface roughness and surface treatment are factors that affect the performance of a FTEXE. FTEXE attachment methods and thermal interface materials also affect the die temperature of the integrated circuit. Thermal adhesive, solder, thermal grease etc. may improve the FTEXE's performance by filling air gaps between the FTEXE and the heat spreader on the device.

A “fluid” as used herein and throughout this disclosure, refers to a substance that continually deforms (flows) under an applied shear stress. As such fluids are a subset of the phases of matter and can include liquids, gases, plasmas and, in some instances, plastic solids. A fluid can be defined as substances that have zero shear modulus or in simpler terms a fluid is a substance which cannot resist any shear force applied to it. As such a fluid may include, but not be limited to, de-ionized water, ethylene glycol, propylene glycol, dielectric fluid, perfluorinated hydrocarbons (e.g. 3M Fluorinert™), synthetic hydrocarbon (e.g. PAO), polyalkylene glycol, silicon oils, fluorocarbon oils, mineral oils, freons, halomethanes, sulphur dioxide, carbon dioxide, ammonia, helium, air, nitrogen, and a nanofluid.

A “nanofluid” as used herein and throughout this disclosure, refers to a carrier liquid dispersed with nano-scale particles (nanoparticles) in order to enhance the heat transfer characteristics of the fluid. Such nanoparticles may include, but are not limited to, copper oxide, alumina, titanium oxide, carbon nanotubes, silica, copper nanorods, and silver nanorods.

A “high thermal conductivity ceramic” (HTCC) as used herein and throughout this disclosure, refers to a ceramic material having high thermal conductivity. An HTCC may include, but is not limited to, alumina (Al₂O₃), sapphire (Al₂O₃), aluminium nitride (AlN), silicon nitride (Si₃N₄), silicon carbide (SiC), mullite (3Al₂O₃.2SiO₂) and cermet (TiC— TiN)

A “high thermal conductivity metal” (HTCM) as used herein and throughout this disclosure, refers to a metal having high thermal conductivity. An HTCM may include, but is not limited to, aluminium, beryllium, copper, gold, molybdenum, silver, and tungsten. For simplicity within the specification an HTCM may also include, but is not limited to, alloys such as copper tungsten, red brass, and bronze.

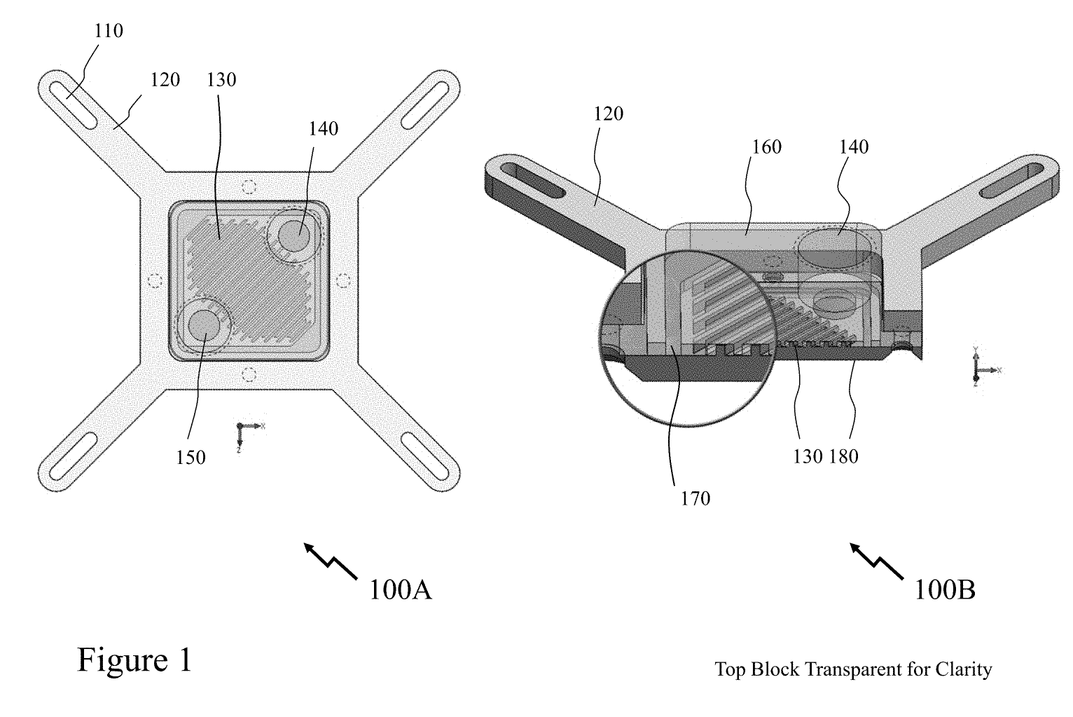

Referring to FIG. 1 in first and second images 100A and 100B there is depicted in plan and perspective views a fluidic thermal exchange element (FTEXE) employing a straight fin profile heatsink according to an embodiment of the invention. As depicted the FTEXE comprises a thermal conductive element (TCE) 180 that contacts, typically, the heat spreader integrated within the CPU package, for example, which is then thermally coupled with the silicon substrate of the silicon electronics forming the CPU, e.g. a microprocessor with associated on-chip memory, and/or the HTCC/HTCM elements of a package housing the CPU such that the TCE 180 has good thermal contact. The upper surface of the TCE 180 has slots 130 formed within it and within the central region of the TCE 180 and a peripheral groove 170. The TCE 180 has a cover 160 disposed atop it with first and second fluid access points 140 and 150 respectively. The cover 160 is sealed fluidically relative to the TCE 180 by an O-ring seal (not depicted for clarity) or equivalent seal to form a cavity for the fluid. The cover 160 being retained relative to the TCE 180 by a frame 120 and multiple attachment points from the frame 120 to the TCE 180 and/or the underlying CPU package. The frame 120 having, as depicted, arms with mounting means 110 for clamping the resultant assembly to a circuit board. Accordingly, the slots 130 are aligned axially with the virtual straight line connecting the first and second fluid access points 140 and 150 respectively. In operation fluid flowing from the first access point 140 to the second access point 150 acquires thermal energy from its contact with the slots 130 and TCE 180 generally, which is subsequently removed from the fluid through a heat exchanger FF-HEX (radiator) and recirculated provides cooling of the CPU. As depicted the cover 160 is transparent to allow visibility of the inner elements of the cover 160, TCE 180, etc. where it would be evident to one of skill in the art that the cover 160 may be opaque or transparent depending upon the material employed.

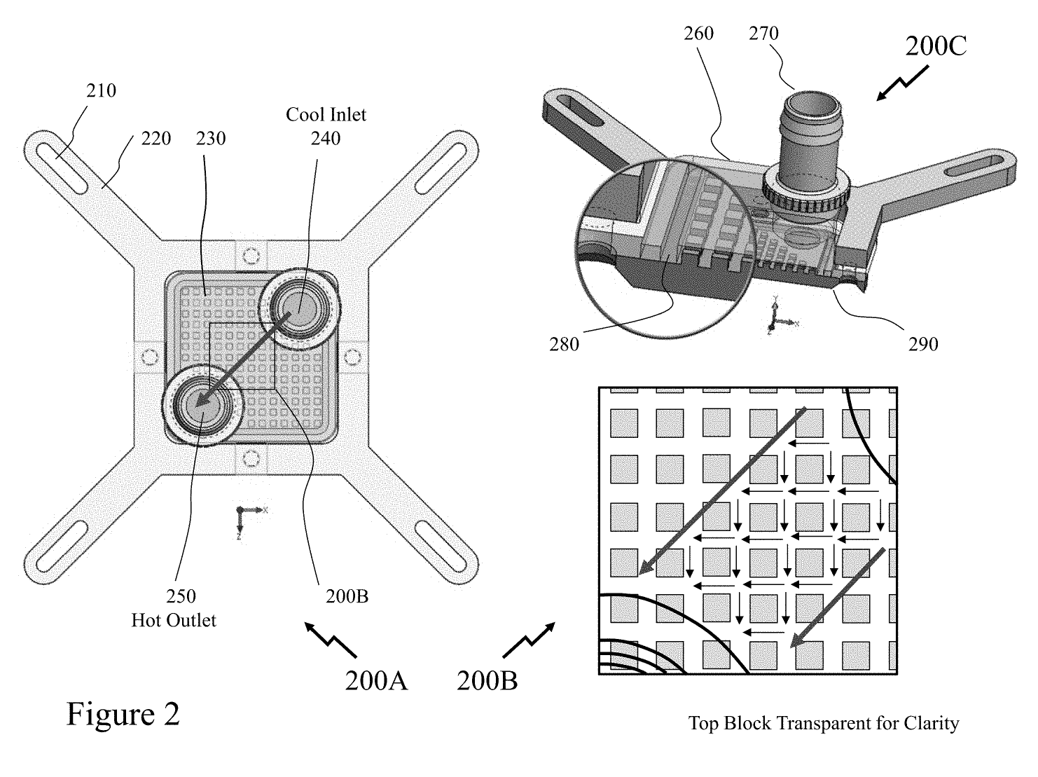

Referring to FIG. 2 in first to third images 200A to 200C respectively there are depicted in plan (200A) and perspective views (200C) together with zoomed detail (200B) a central processing unit (CPU) block employing a pin fin profile heatsink according to an embodiment of the invention with straight profile. As depicted the FTEXE comprises a thermal conductive element (TCE) 290 that contacts, typically, the heat spreader integrated within the CPU package, for example, which is then thermally coupled with the silicon substrate of the silicon electronics forming the CPU e.g. a microprocessor with associated on-chip memory, and/or the HTCC/HTCM elements of a package housing the CPU such that the TCE 290 has good thermal contact. The upper surface of the TCE 290 has thermal interface projections (TIPs) 230 formed within it and within the central region of the TCE 290 and a peripheral groove 280. The TIPs 230 are laid out in the cavity of the FTEXE according to one or more repetitive patterns. The patterns are “cells” were thermal transfer occurs from the TIPs to the Thermal Transport Fluid. The TCE 290 has a cover 260 disposed atop it with first and second fluid access points 240 and 250 respectively. The cover 260 is sealed fluidically relative to the TCE 290 by an O-ring seal (not depicted for clarity) or equivalent seal to form a cavity for the fluid. The cover 260 being retained relative to the TCE 290 by a frame 220 and multiple attachment points from the frame 220 to the TCE 290 and/or the underlying CPU package. The frame 220 having, as depicted, arms with mounting means 210 for clamping the resultant assembly to a circuit board. Accordingly, the TIPs 230 are aligned axially with the virtual straight line connecting the first and second fluid access points 240 and 250 respectively. In operation fluid flowing from the first access point 240 to the second access point 250 acquires thermal energy from its contact with the TIPs 230 and TCE 290 generally, which is subsequently removed from the fluid through a heat exchanger (e.g. radiator) and recirculated provides cooling of the CPU. As depicted the cover 260 is transparent to allow visibility of the inner elements of the cover 260, TCE 290, etc. where it would be evident to one of skill in the art that the cover 260 may be opaque or transparent depending upon the material employed. Coupled to each of the first and second fluid access points 240 and 250 respectively are coupling elements 270 allowing connection of the fluid tubing to them and its retention through the ribs with optionally added clamps. Referring to second image 200B a zoomed view of the central region of the FTEXE is depicted showing the matrix, a plurality of TIPs 230 arranged in cells, of TIPs 230 is shown together with the overall global and local fluid flows through arrows. Accordingly, as the Thermal Transport Fluid flows from first fluid access point 240 to second fluid access point 250 it flows through the channels between the TIPs 230 resulting in increased turbulence and contact with the TIPs 230 increasing thermal coupling and mixing.

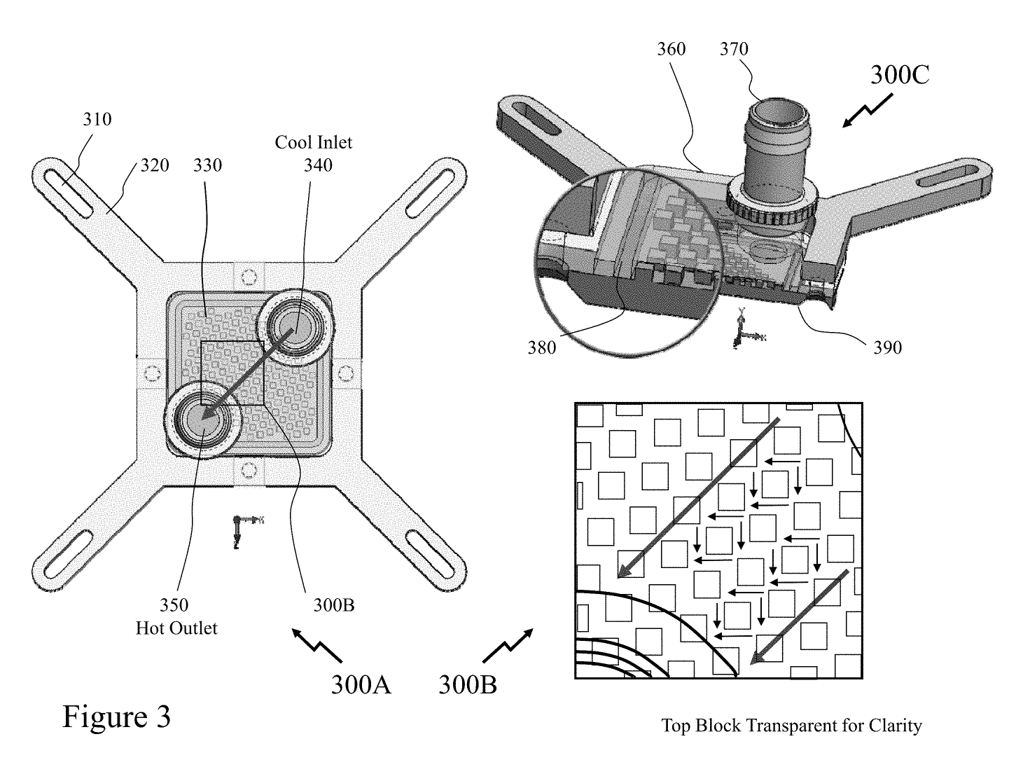

Referring to FIG. 3 in first to third images 300A to 300C respectively there are depicted in plan (300A) and perspective views (300C) together with zoomed detail (300B) a central processing unit (CPU) block employing a pin fin profile heatsink according to an embodiment of the invention with staggered profile. As depicted the FTEXE comprises a thermal conductive element (TCE) 390 that contacts, typically, the heat spreader integrated within the CPU package, for example, which is then thermally coupled with the silicon substrate of the silicon electronics forming the CPU, e.g. a microprocessor with associated on-chip memory, and/or the HTCC/HTCM elements of a package housing the CPU such that the TCE 390 has good thermal contact. The upper surface of the TCE 390 has TIPs 330 formed within it and within the central region of the TCE 390 and a peripheral groove 380. The TCE 390 has a cover 360 disposed atop it with first and second fluid access points 340 and 350 respectively. The cover 360 is sealed fluidically relative to the TCE 390 by an O-ring seal (not depicted for clarity) or equivalent seal to form a cavity for the fluid. The cover 360 being retained relative to the TCE 390 by a frame 320 and multiple attachment points from the frame 320 to the TCE 390 and/or the underlying CPU package. The frame 320 having, as depicted, arms with mounting means 310 for clamping the resultant assembly to a circuit board. Accordingly, the TIPs 330 are aligned axially with the virtual straight line connecting the first and second fluid access points 340 and 350 respectively. In operation fluid flowing from the first access point 340 to the second access point 350 acquires thermal energy from its contact with the TIPs 330, a plurality of TIPs 330 arranged in cells, and TCE 390 generally, which is subsequently removed from the fluid through a heat exchanger (e.g. radiator) and recirculated provides cooling of the CPU.

It would be evident to one skilled in the art that the peripheral groove 380 in FIG. 3, as well as peripheral grooves 170 and 280 in FIGS. 1 and 2, are only required where an O-ring or similar physical fluidic seal is employed. In other embodiments of the invention this may not be presented as alternative fluidic sealing techniques as known in the art may be employed. As depicted the cover 360 is transparent to allow visibility of the inner elements of the cover 360, TCE 390, etc. where it would be evident to one of skill in the art that the cover 360 may be opaque or transparent depending upon the material employed. Coupled to each of the first and second fluid access points 340 and 350 respectively are coupling elements 370 allowing connection of the fluid tubing to them and its retention through the ribs with optionally added clamps. Referring to second image 300B a zoomed view of the central region of the FTEXE is depicted showing a matrix of TIPs 330 arranged in cells together with the overall global and local fluid flows through arrows. Accordingly, as the fluid flows from first fluid access point 340 to second fluid access point 350 it flows through the channels between the TIPs 330 resulting in increased turbulence and contact with the TIPs 330 increasing thermal coupling and mixing.

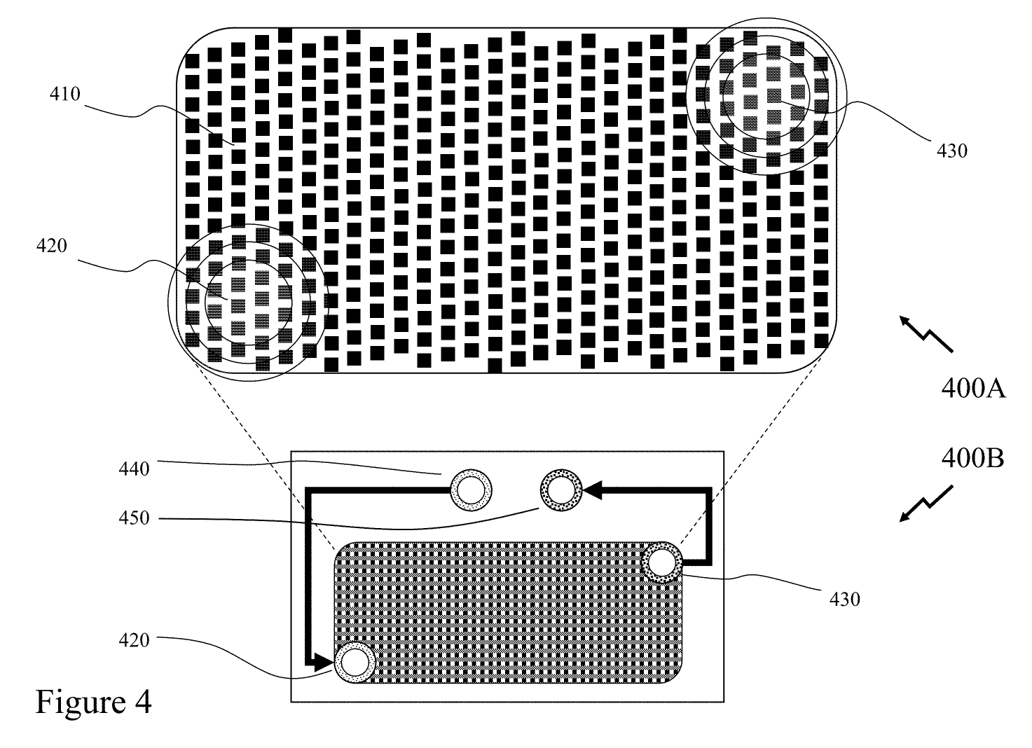

Now referring to FIG. 4 there is depicted a graphical processing unit (GPU) block 400B employing a single path large area heatsink 400A according to an embodiment of the invention such as described supra in respect of FIGS. 1 to 3 even though within first image 500A a staggered pin fin 410 geometry (deployed from a plurality of cells of TIPs 410) is depicted. Accordingly, first fluid access 420 of the heatsink 400A is coupled to inlet 440 of the FTEXE 400B and second fluid access 430 of the heatsink 400A is coupled to outlet 450 of the FTEXE 400B. Accordingly, FTEXE 400B may provide thermal management of a CPU.

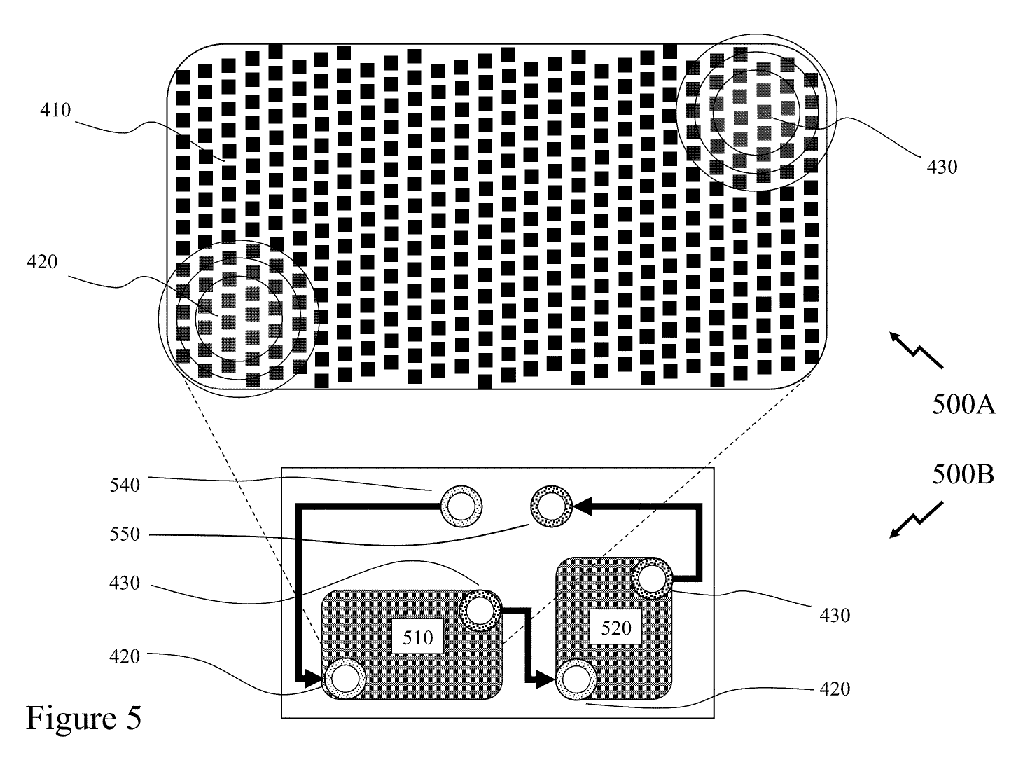

Now referring to FIG. 5 there is depicted a graphical processing unit (GPU) block 500B employing a pair of dual heatsinks 500A according to an embodiment of the invention such as described supra in respect of FIGS. 1 to 3 even though within first image 500A a staggered pin fin 410 geometry (deployed from a plurality of cells of TIPs 410) is depicted. Accordingly, first fluid access 420 of the first heatsink 510 is coupled to inlet 540 of the FTEXE 400B and second fluid access 430 of the second heatsink 520 is coupled to outlet 550 of the FTEXE 400B. The second fluid access 430 of the first heatsink 510 is coupled to the first fluid access 430 of the second heatsink 520. Accordingly, FTEXE 400B may provide thermal management of a pair of CPU elements or a CPU and a graphics accelerator circuit for example.

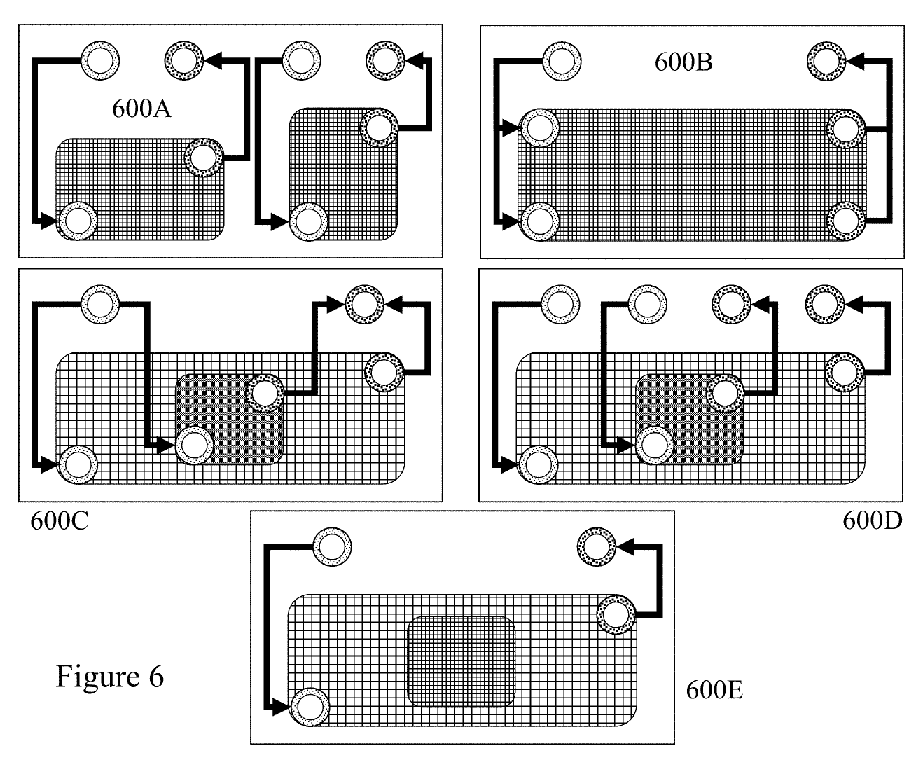

Referring to FIG. 6 there are depicted first to fifth GPU configurations 600A to 600E respectively for single and multiple path heatsinks according to embodiments of the invention wherein these depict:
First GPU configuration 600A comprising a pair of CPU heatsinks coupled individually to external fluidic circuits;
Second GPU configuration 600B comprising a single CPU heatsink coupled to a single external fluidic circuit but with a pair of fluid inlet ports and a pair of fluid outlet ports to the CPU heatsink;
Third GPU configuration 600C comprising a single CPU heatsink coupled to a single external fluidic circuit but designed with two different regions of TIPs (comprising a plurality of TIPs in cells used to layout or place these regions or slots) due to different thermal requirements (optionally the two regions may be fluidically coupled within the CPU heatsink or fluidically isolated);
Fourth GPU configuration 600D comprising a single CPU heatsink coupled to a pair of external fluidic circuits but designed with two different regions of TIPs (comprising a plurality of TIPs in cells used to layout or place these regions or slots) due to different thermal requirements (optionally the two regions may be fluidically coupled within the CPU heatsink or fluidically isolated); and
Fifth GPU configuration 600E comprising a single CPU heatsink coupled to a single external fluidic circuit but designed with two different regions of TIPs (comprising a plurality of TIPs in cells used to layout or place these regions or slots) due to different thermal requirements which are fluidically coupled within the CPU heatsink.

With respect to the material selection of the FTEXEs then high thermal conductivity material are preferred such as HTCM and HTCC materials as unlike the fluid-fluid heat exchanger removing the heat from the circulating fluid through the FTEXE power density factors are important as the CPU/GPU or other electronics are dissipating power in very small areas. Within embodiments of the invention TCE, such as TCEs 180, 290 and 390 in FIGS. 1 to 3 respectively may be formed from a single material or they may be formed from multiple materials. For example, the slots 130 (FIG. 1) or TIPs 230/300, a plurality of TIPs 230/330 arranged in one or more cells, (FIGS. 2 and 3 respectively) may be formed from a different material to that for the larger area TCE. Alternatively, the TCE may be single material inserted into a peripheral piece-part or piece-parts in order to employ a lower cost material and/or lower thermal conductivity material for the periphery where the frame, O-ring etc. provide mechanical mounting, fluid seal etc. In these instances, the TCE may be discrete from the periphery or it may be attached through one or more techniques to provide mechanical joining including, but not limited, interference fit, welding, brazing, soldering, and adhesives/epoxies according to factors including, but not limited to, the materials being joined, operating temperature ranges, cost, and ease of manufacturing/assembly. Internally, surfaces exposed to the recirculating fluid may be surface treated to reduce corrosion, material aggregation, reaction with recirculating fluid etc. Optionally, the internal surface may also be coated with a material to improve thermal conductivity to the slots 130 or TIPs 230/300 (comprising a plurality of TIPs in cells used to layout or place to effect thermal energy transfer to the Thermal Transport Fluid) such as metallic thin films of HTTMs such as gold, silver, and copper, for example, or a HTTC thin films such as aluminium nitride or another HTTC material such as artificial diamond, graphene, and carbon nanotubes.

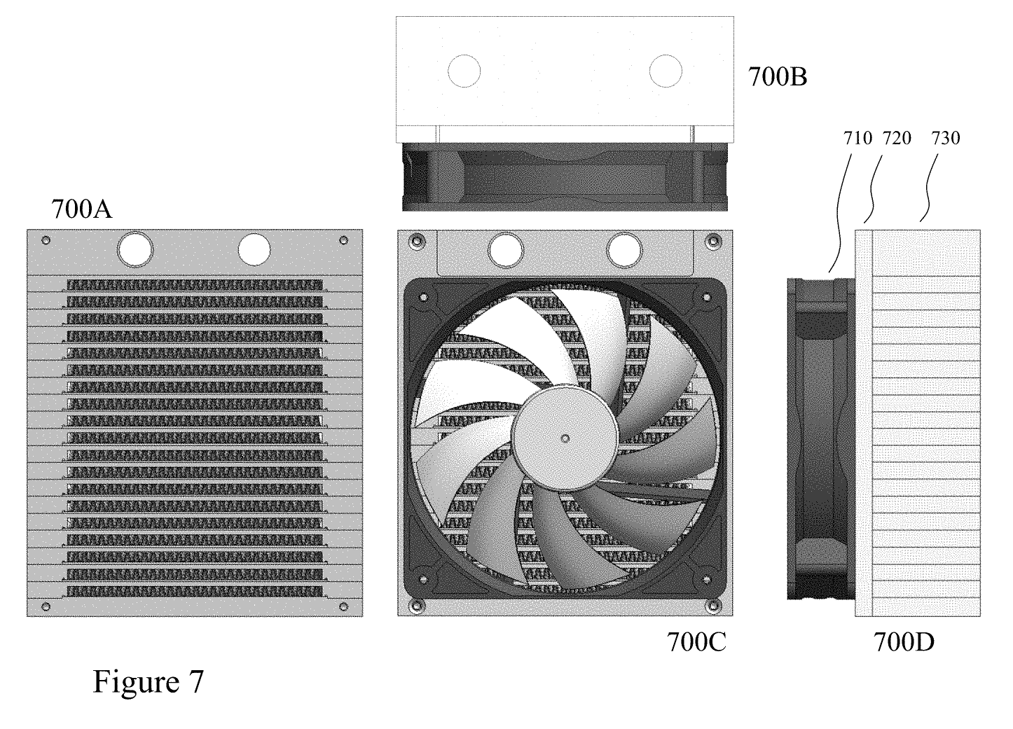

Multiple phases of materials, nominally a fluid used to transport thermal energy from the FF-HEX (such as air (gases) and water (liquids)), can be propelled thru the FF-HEX (radiator) or the FF-HEX can be immersed in the second fluid. The FF-HEX can work on different, or the same, fluid as the Thermal Transport Fluid allowing for multiple phases of same within and around the FF-HEX. FIGS. 7 and 8 depict a fluid-fluid heat exchanger (FF-HEX or radiator) exploiting modular design methodology according to an embodiment of the invention. In FIG. 7 standard rear elevation 700A, front elevation 700C, side elevation 700D and top elevation 700B views are presented. Accordingly, a FLUid Mover (FLUM) 710, e.g. a fan, is mounted to the front of a Fluid-Fluid Exchanger Block (FFEB) 730 via a coupling plate 720. In FIG. 8 first to third perspective views 800A to 800C are depicted wherein:
First perspective view 800A depicts the full FF-HEX comprising FLUM 710, coupling plate 720, and FFEB 730;
Second perspective view 800B depicts the FF-HEX without FLUM 710 comprising coupling plate 720 and FFEB 730; and
Third perspective view 800C depicting the FFEB 730 as comprising bottom plate 810, top plate 820 and a plurality of Fluid-Fluid Thermal Coupling Elements (FFTCEs) 830. Those skilled in the art will appreciate that FFTCEs may be cooled by fans as depicted in FIGS. 7 and 8 or immersed in a vat of cooling fluid.

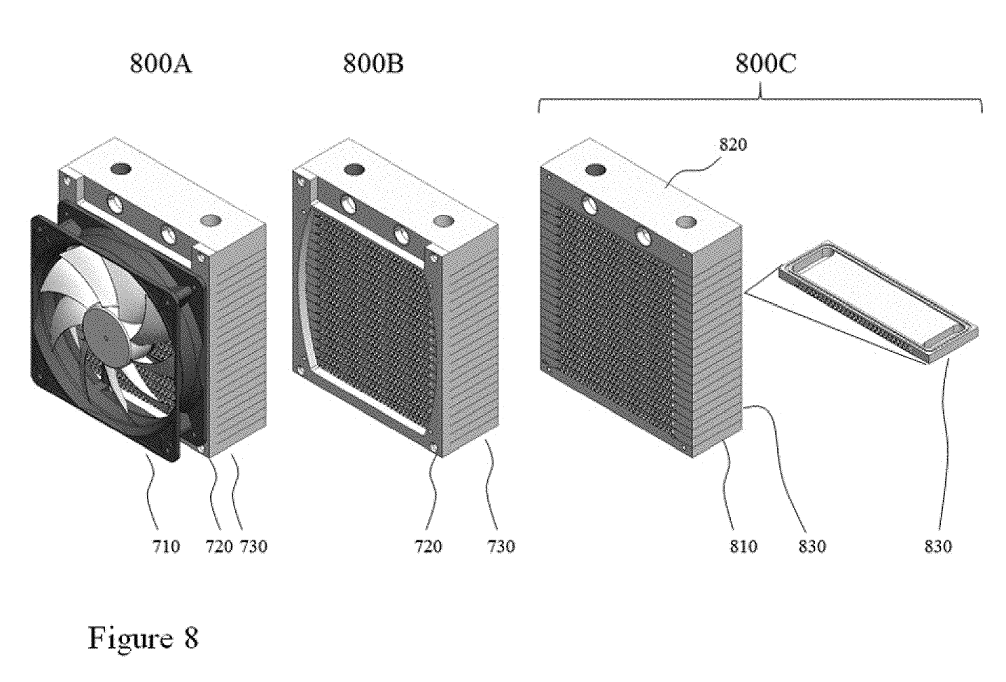

Referring to FIG. 9 there is depicted the FF-HEX according to FIGS. 7 and 8 in exploded perspective view. Accordingly, depicted are top plate 820, bottom plate 810 and a plurality of FFTCEs 830 exploded into their component elements, namely frames 920, first fluid thermal interface elements (FTINEs) 930 and second FTINEs 910. Accordingly, the frames 920 stack upon bottom plate 810 and have top plate 820 mounted atop and the assembly mechanically restrained to form the body of the FFEB 730. Fluid access ports within top plate 820 couple to fluidic channels within each end of the frames 920 which are coupled through the bottom plate 810.

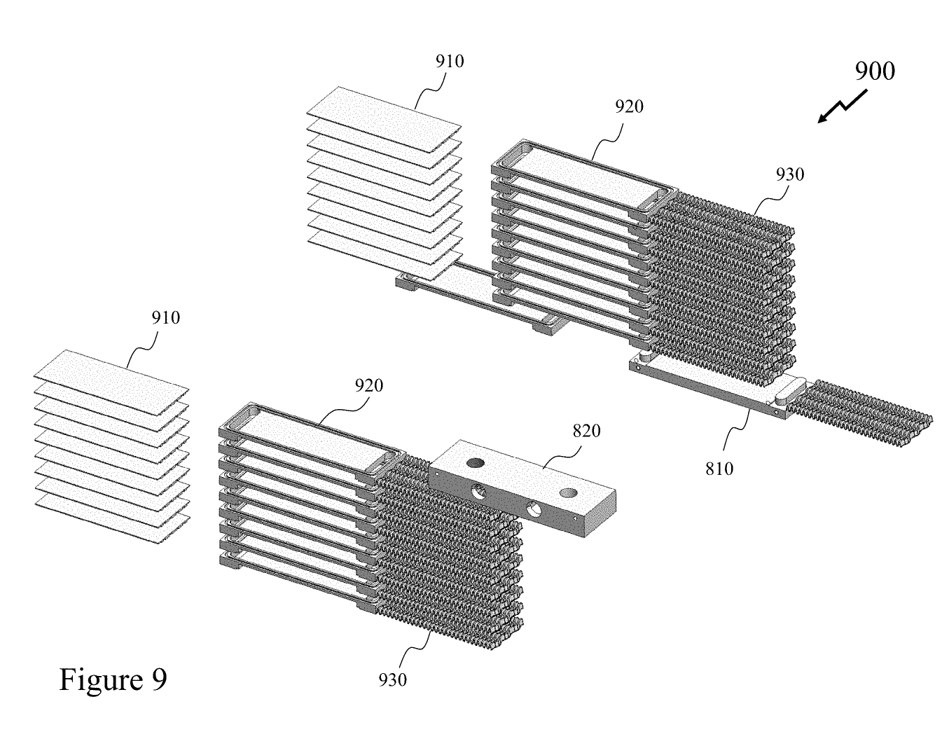

Accordingly, fluid enters the top plate 820 on one port, flows down the access channels within the frame 920 on one side and back up through the access channels on the other end of the frame 920 and through bottom plate 810 back to the outlet (another port) in top plate 820. The second FTINEs provide fluidic paths from the access channels on each end of each frame 920 to the access channel on the other end. Disposed between adjacent frames 920 are first FTINEs 930. The fluid flowing through the first FTINEs 930 arising from the FLUM 710 within embodiments of the invention described and depicted in respect of FIGS. 7 to 9 respectively. This overall flow being depicted in first image 1000 within FIG. 10 such that the fluid coupled to the FTEXE(s) flows from upper right through to upper left losing thermal energy to the fluid moving perpendicular to the plane of the FFTEB 730.

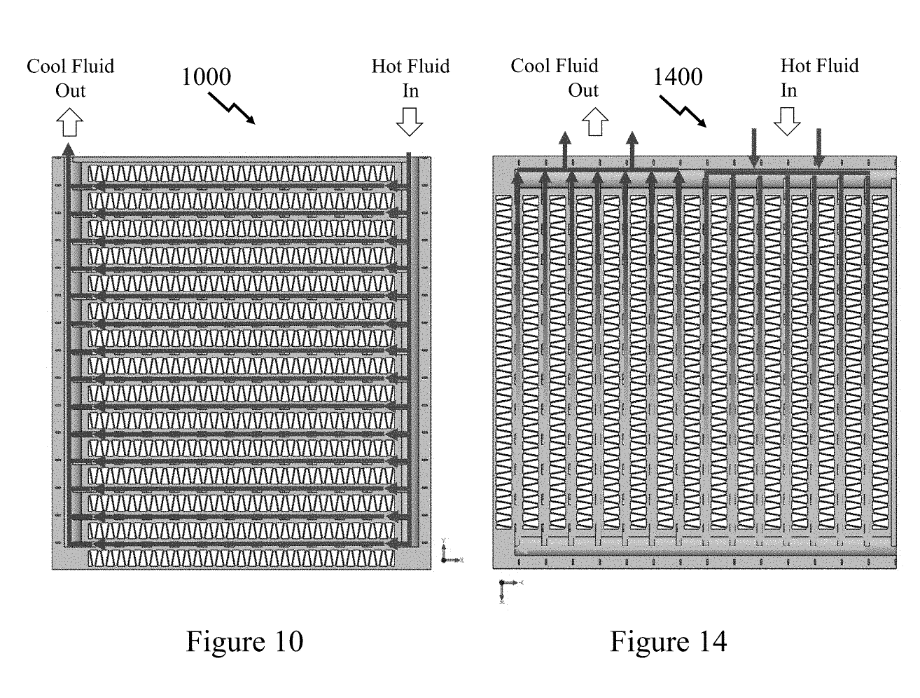

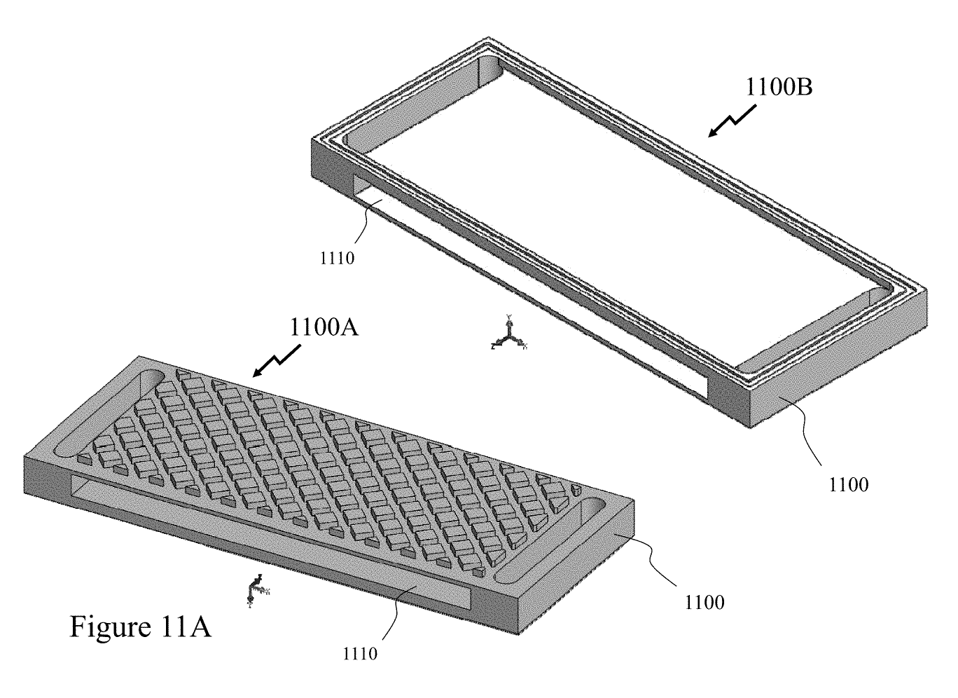

Now referring to FIG. 11A there are depicted top and bottom perspective views 1100A and 1100B respectively of an individual EXchange Unit Cell (EXUC) 1100 according to an embodiment of the invention which forms the basis of the modular design (radiator) depicted in FIGS. 7 to 10 respectively. As depicted the EXUC 1100 comprises a single piece part combining the frame 920 and second FTINE 910 within a single piece part that may be, for example, cast or alternatively machined etc. Accordingly, the EXUC 1100 comprises an open recessed portion on the base to allow the thermal interface element (TIE) 930 of the next EXUC 1100 to fit within providing a fluid path between the fluid channels at either end of the EXUC 1100. The first FTINE (not depicted for clarity) is inserted into the slot 1110 through the EXEC 910 wherein examples of such first FTINE are depicted in FIG. 11B with first and second FTINE inserts 1100C and 1100D depicting serpentine and linear designs respectively. It would be evident to one of skill in the art that other designs may be employed without departing from the scope of the invention. Beneficially structures such as first and second FTINEs 1100C and 1100D may be stamped as well as formed through other processes such as casting. It would be further evident that such a FTINE may also exploit arrays of TIPs (from cellular elements), TIEs and other structures similar to those described in respect of pin fin FTEXEs supra in FIGS. 2 and 3 respectively. Alternatively, continuous channels with increased meandering may be employed.

Further, as discussed within this specification FF-HEX may be designed and implemented that are not repetitions of the same single EXUC but may exploit multiple EXUCs. Additionally, the design of an EXUC itself may not be uniform in contrast to the embodiments of the invention described and depicted within respect of FIGS. 1 to 18. Accordingly, due to the characteristics of the thermal transfer process between each fluid and its associated interfaces there may be a variation within the design of the EXUC in one or more dimensions. For example, the design closer to the higher temperature side may be designed for higher fin density or higher fluid flow through the FTINE (i.e. offering lower resistance) whereas to the colder side the fin density may reduce or have lower fluid flow through the FTINE. In some embodiments of the invention the fluid flow in these different ends may be coupled to different fluidic circuits of the fluid extracting thermal energy from the FTINE. In essence, variants of the EXUC may mimic variants of the FTEXE with multiple sections/circuits such as described and depicted in respect of FIG. 6.

Optionally, within some embodiments of the invention the density of the FTINE elements may vary along the length of the EXUC 1100 due to variations in thermal transfer arising from varying temperature of the fluid circulating within the FF-HEX along the EXUC 1100 or through flow variations in the fluid flowing through the FTINE to extract thermal energy.

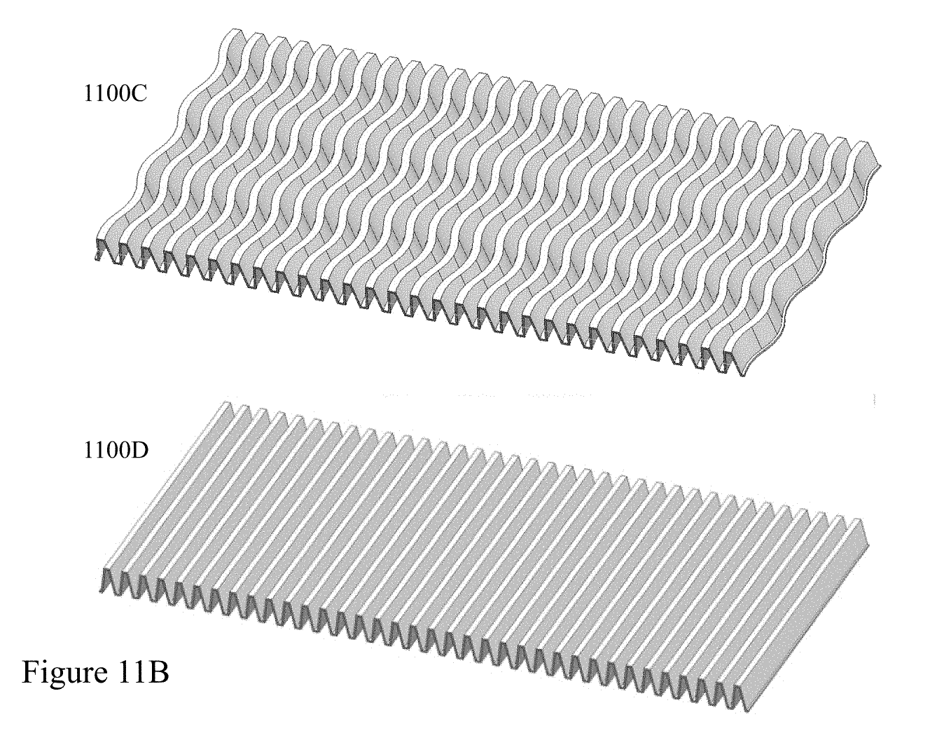

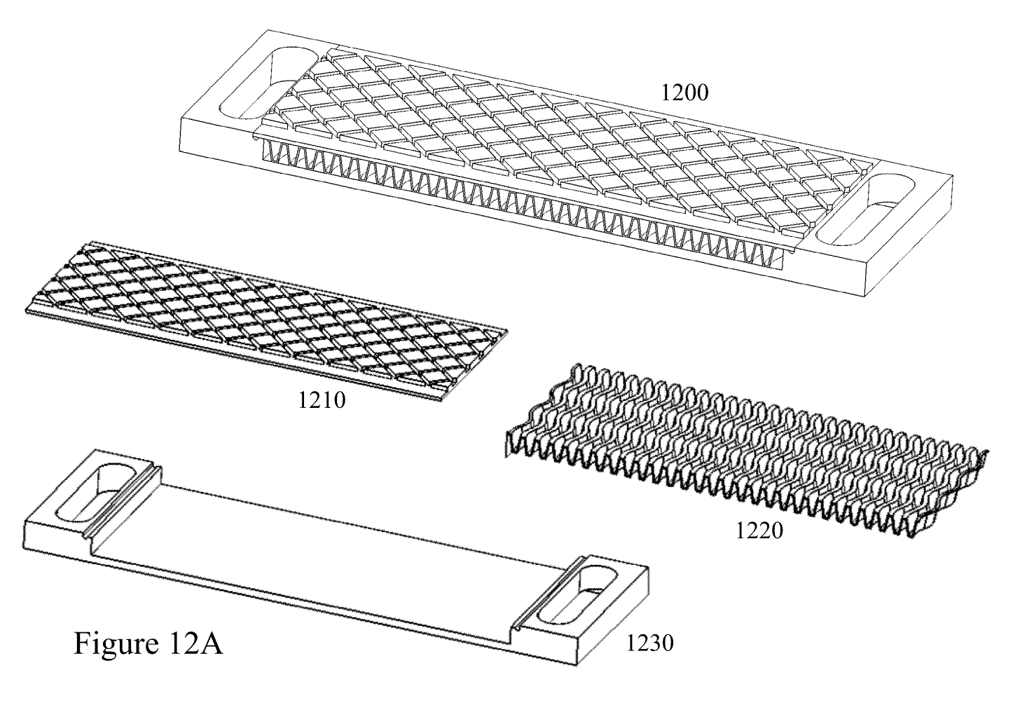

Now referring to FIG. 12A there is depicted an exploded perspective view of an alternate individual unit cell design according to an embodiment of the invention to EXUC 1100 depicted in FIG. 11 and aligning with that depicted in FIG. 9. Accordingly, as depicted the EXchange Unit Cell (EXUC) is depicted as EXUC 1200 together with its three components:
Body 1230 corresponding to frame 920 in FIG. 9;
First fluid interface 1220 corresponding to first fluid thermal interface elements (FTINEs) 930 in FIG. 9 which couples thermal energy from the fluid flowing (recirculating) within the FF-HEX and second FTINEs 910 to the second fluid interface 1210 and therein to the fluid flowing through that aspect of the FF-HEX; and
Second fluid interface 1210 corresponding to second FTINE 910 in FIG. 9.

EXUC 1200 may in some instances offer an advantage over EXUC 1100 in that the thermal transfer characteristics of the second FTINE 1210 may be designed in a first material which exhibits high thermal transfer coefficient but due to its cost makes forming the entire EXUC 1100 expensive. Accordingly, the body 1230 may be formed from a different material selected based upon its requirements. Referring to FIG. 12B there is depicted schematically the overall fluid flows together with the discrete fluid flows within the individual fluid flows within the second FTINE 1210 as directed from the staggered pin fin geometry such that the fluid #1 flow splits and merges at every “pin” inducing mixing and velocity changes which favour heat exchange. Note in FIG. 12B that there are clearly multiple cells representing multiple layouts and 3-dimensional geometries of “pins” that are depicted as covering the area where a plurality of the pins exchange the thermal energy to the Thermal Transport Fluid. Other cells may be present to manage other aspects such a plurality of the fluid flow characteristics of the boundary layer, inlet/outlet, structural elements, or manufacturing artifacts.

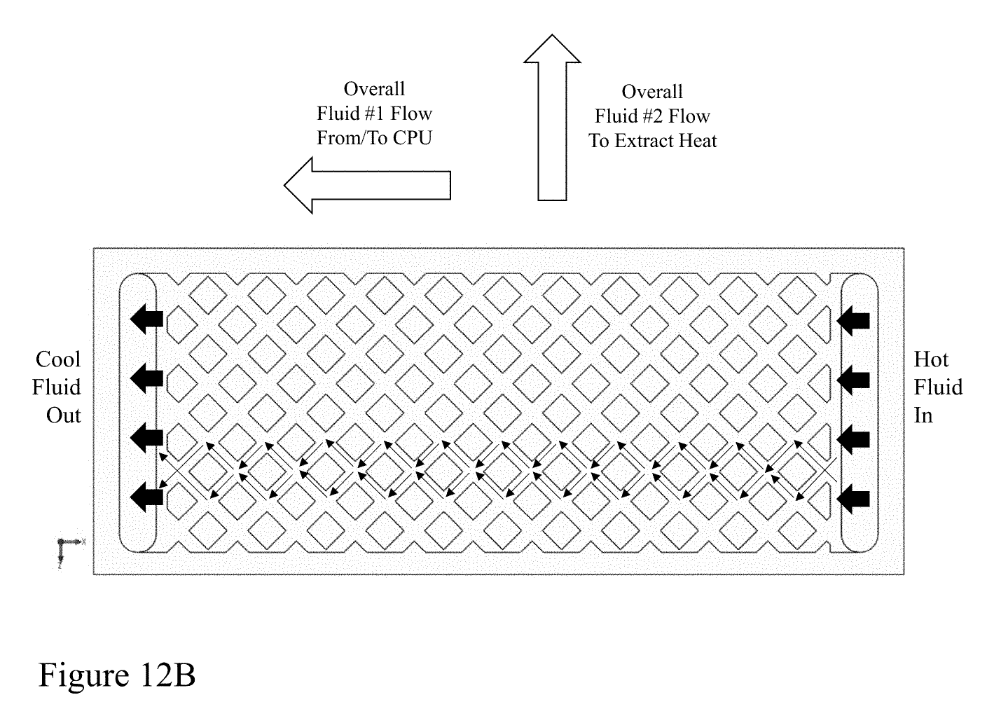

Referring to FIG. 13 there is depicted a FF-HEX according to the modular design methodology according to an embodiment of the invention with alternate fluid flow within the modular unit cells. As depicted the FF-HEX comprises front plate 1310A, rear plate 1310B, lower plate 1360 and upper plate 1350. Disposed between these is an array of a plurality of plurality of exchange unit cells (EXUCs) comprising body 1320, first fluid thermal interface elements (FTINEs) 1330 and second FTINEs 1340 which are all sandwiched together and mechanically held together. For example, as indicated the plurality of bodies 1320, first FTINESs 1330 and second FTINES 1340 fit within recesses within the lower plate 1360 and upper plate 1360 to mechanically retain their movement and these are then held in rigid position relative to one another via the front and rear plates 1310A and 1310B respectively.

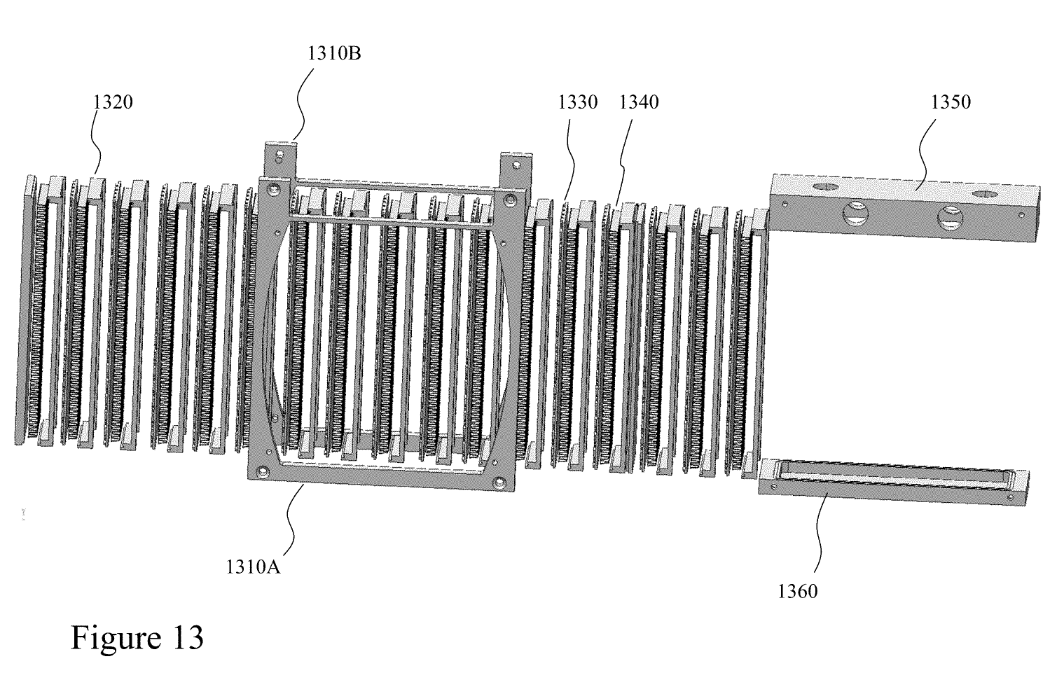

Accordingly, referring to FIG. 14 there is depicted the fluid flow within the FF-HEX of FIG. 13 according to an embodiment of the invention wherein the fluid recirculating to the FTEXE(s) to have thermal energy removed is coupled into the inlet(s) on the upper right wherein the fluid flows through the unit cells (EXUCs) to the bottom plate before flowing back up to the outlet(s) on the upper left. It would be evident that alternatively, the fluid may flow down through all EXUCs or down through 75% and up through 25% or down 35% and up through 65% according to the overall thermal transfer profile being sought. Different ratios may be employed or the design may be such that the fluid simply flows in one direction through all EXUCs such as depicted in FIG. 10. It would be evident that in addition to the number of EXUCs having fluid flowing in different directions that the design of the actual EXUCs may similarly vary such that, for example, 65% of the EXUCs are of “Design A” with a flow from the inlet to the coupling between the first and second EXUC sets wherein the flow is then within 35% of the EXUCs that of “Design B.” Whilst such designs provide the lowest complexity to the external it would be evident that other designs may be employed such as central inlet with outlets disposed with side, central outlet with inlets disposed either side, multiple inlets and outlets, etc.

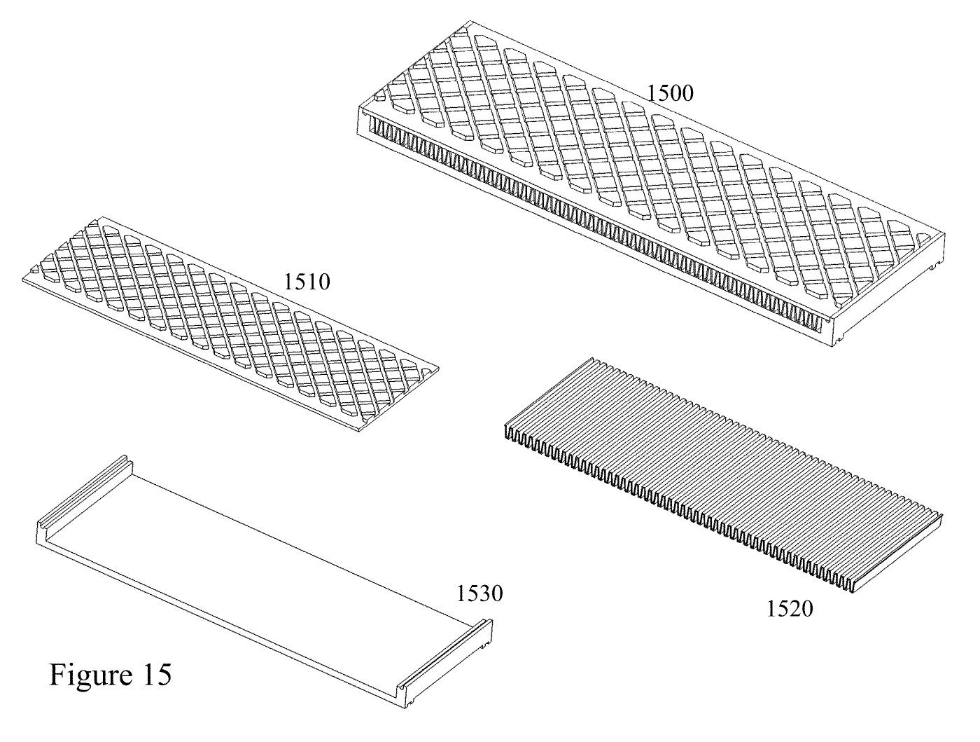

FIG. 15 there is depicted an exploded perspective view of an individual unit cell, EXUC 1500, according to an embodiment of the invention which employed within the modular design FF-HEX depicted in FIG. 14. Accordingly, EXUC 1500 comprises:
Body 1530 providing mechanical integrity and retaining the first and second TFINEs 1510 and 1530 respectively and corresponds to body 1230 in FIG. 12A but is now absent the fluid access portions at either end;
First FTINE 1520 corresponding to first second FTINE 1220 in FIG. 12A and may in fact be identical allowing common piece-part to two FF_HEX designs or different according to the design requirements of the FF-HEX, wherein first FTINE 1520 couples thermal energy from the fluid flowing (recirculating) within the FF-HEX and across the first FTINEs 1210 to the second fluid; and
Second FTINE 1510 corresponding to second FTINE 1210 in FIG. 12A.

As with respect to EXUC 1200 in FIG. 12 the EXUC 1500 in FIG. 15 may be designed such that the thermal transfer characteristics of the second fluid interface 1510 may be designed in a first material which exhibits high thermal transfer coefficient but due to its cost makes forming the entire EXUC 1100 expensive. Accordingly, the body 1530 may be formed from a different material selected based upon its requirements.

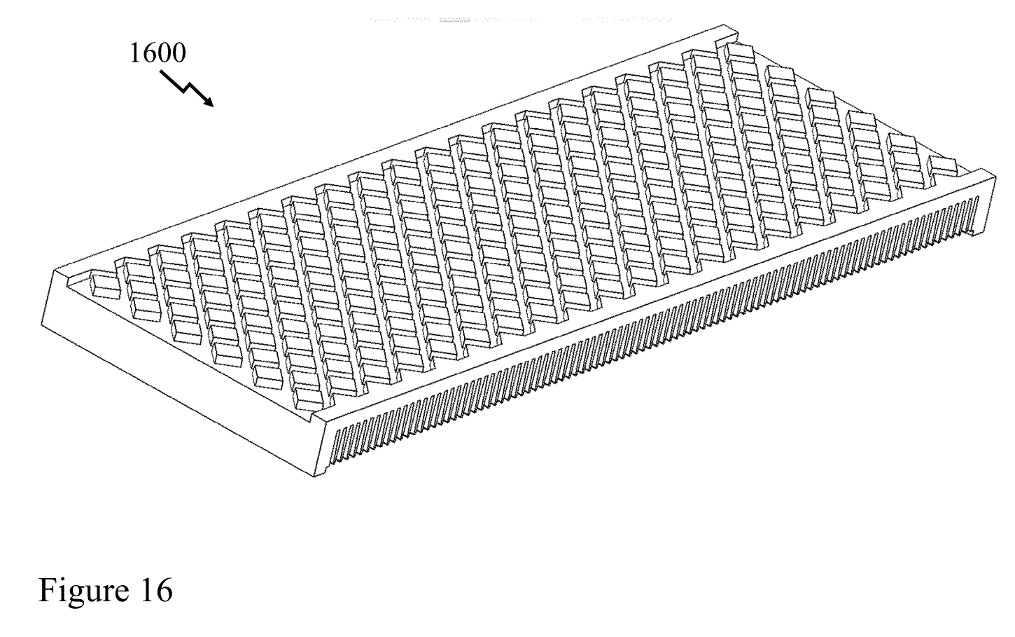

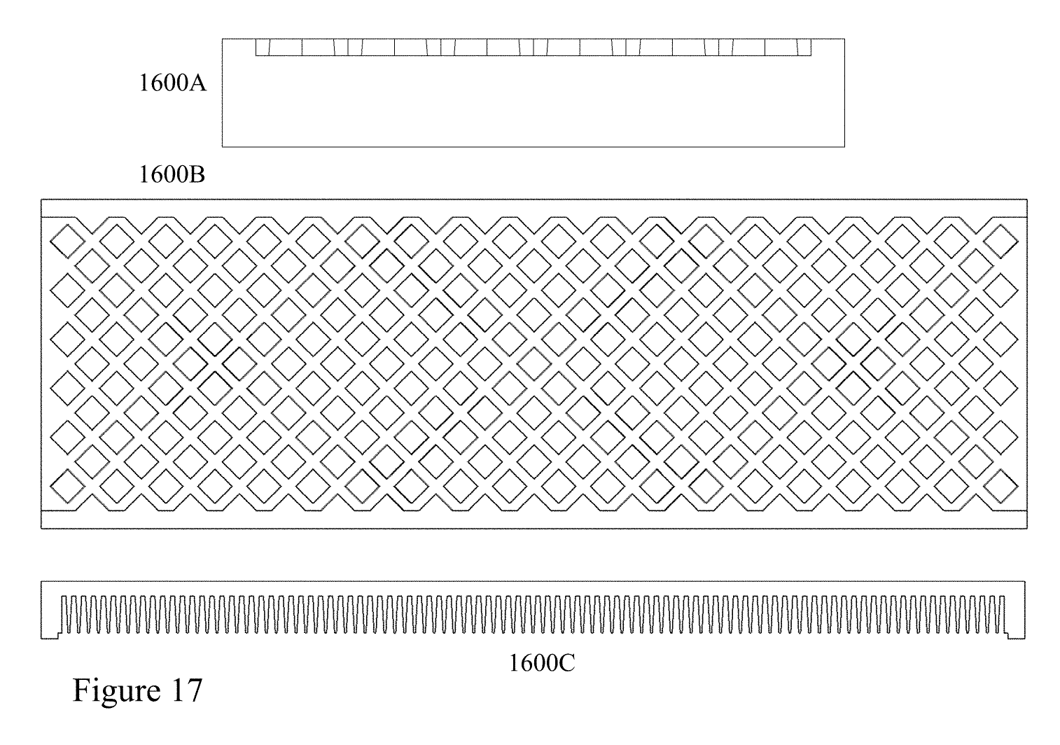

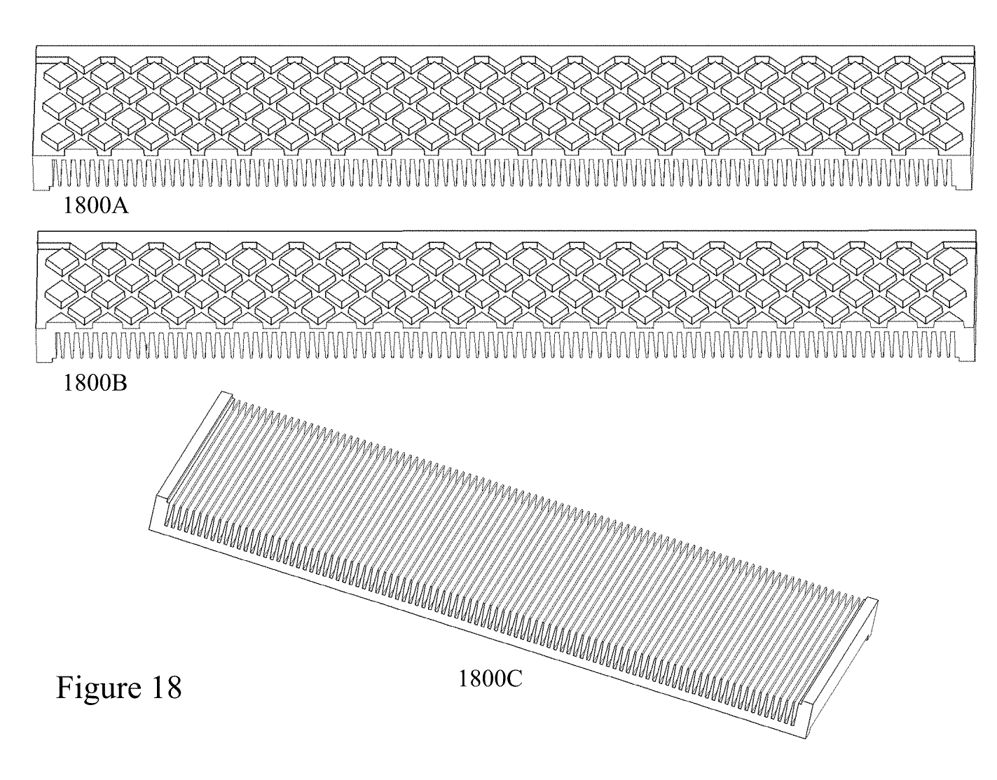

Now referring to FIG. 16 there is depicted a perspective view of a single piece FF-HEX individual unit cell, EXUC 1600, according to an embodiment of the invention which may be employed within the modular design FF-HEX depicted in FIG. 14. EXUC 1600 is depicted in first to third elevation views 1600A to 1600C respectively in FIG. 17 which depict the side elevation, plan elevation, and front elevation respectively of the single piece individual unit cell depicted in FIG. 16. In contrast in FIG. 18 there are depicted first perspective cross-sectional view 1800A, second perspective cross-sectional view 1800B, and bottom perspective view 1800C respectively. Whilst the EXUC depicted in FIGS. 16 to 18 exploits TIPs within the upper TFINE surface which interfaces to the recirculating fluid within the FF-HEX to/from the FTEXE it may alternatively exploit fins and/or a combination of fins and TIPs (using a plurality of cell definitions and groupings) on the lower TFINE surface.

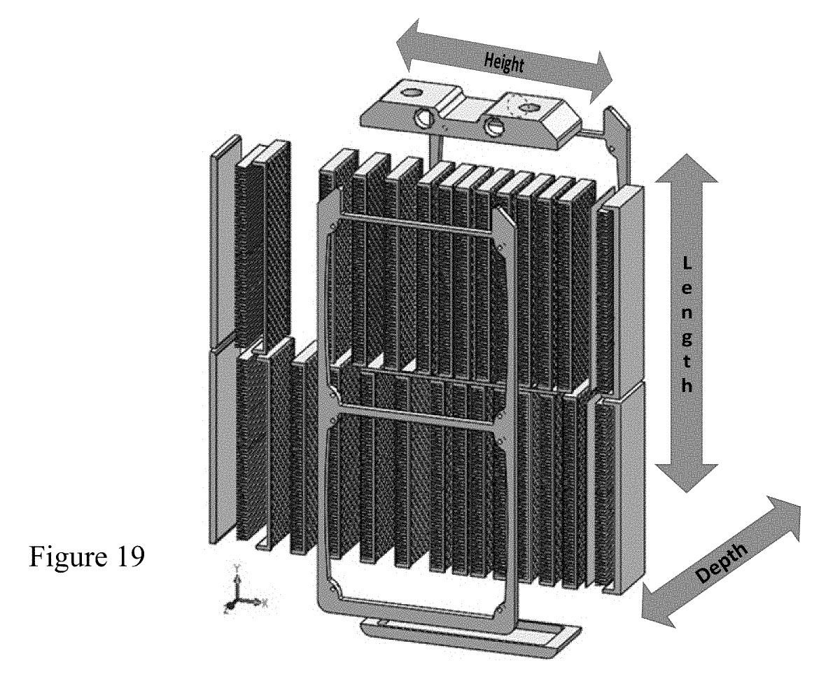

Alternate embodiments of the exemplary embodiments can be related using the dimensional conventions outlined in FIG. 19. Along the dimension illustrated as “Depth” a plurality of multiple FF-HEX units could be arranged with alternate embodiments incorporating a plurality of Fluid-Movers in a variety of physical arrangements. In similar fashion along the dimension illustrated as “Height” additional EXUC can be arranged with a plurality of Thermal Transport Fluid flows. In similar fashion an alternate embodiment might employ multiple Fluid-Movers across the dimensions labelled “Height”, “Length”, or “Depth” in a 3-D configuration. The plurality of Fluid Movers (effecting movement on a plurality of the Thermal Transport Fluids) can be arranged in many different alternate embodiments with the desires of different industries, applications, and requirements. Along the dimensions illustrated as “Height” or “Length” additional FF-HEX units could be arranged with a plurality of paths and linkages using the connection ports labelled in FIG. 13 as element 1350. Alternate embodiments using multiple Fluid Movers, additional linkages, and various Thermal Transport Fluid paths on respective sides of the resulting radiator are possible.

The Fluid Transport Fluid flow thru/along/in cells of TIPs (in embodiments of the FT-EXE and FF-HEX elements) also reflect the relationships of the cross-sectional fluid flow within the fluid flow path wherein the TIPs are present. Two forms of Thermal Transport Fluid Flow “bypass” can occur: 1) Where the fluid flow path does not cause an encounter between the Thermal Transport Fluid and a TIP, or 2) Where the fluid flow path is blocked by dynamic fluid flow properties from a thermal exchange between a TIP and the Thermal Transport Fluid. Thermal transport fluid bypass occurs when the three dimensional placement, flow paths, or geometries of pin placement leave a space (such as a gap, channel, or unregulated space) where thermal transport fluid can bypass the thermal exchange between the thermal load or in a fluid-fluid heat exchange context. A preferred embodiment of the illustrated Apparatus does not have bypass spaces between the surface of the pins not connected to the thermal load or thermal exchange surface and the opposing surface. Due to pin construction, thermal load, requirements, or flow path design alternate embodiments of the Apparatus may, or may not, have bypass spaces present. The industry, application, and requirements driving a specific alternate embodiment design are used by the design methodology to determine the presence, or absence, or indiscriminate presence or absence, of bypass spaces. Thus, a thermal transport fluid flow in a relatively low thermal generation load environment may allow a different manufacturing process for a device where bypass spaces are present for reasons of reducing costs, providing compensation for choices of thermal transport fluids, facilitating a longer operating period or operating envelope for an embodiment of the Apparatus in a degraded (contaminated or out-of-spec environment), or where choices of materials allow other design choices. Even in these cases the disclosure foresees that the alternate apparatus embodiments are within the teachings of the disclosure.

It would be evident that the EXUC designs, such as those depicted in respect of FIGS. 9, 11A-12B, and 15-18 may be formed using one or more manufacturing processes including, but not limited to, casting, machining, extruding, stamping, co-firing, additive manufacturing according to the component of the EXUC and the design requirements, material, dimensions, cost, etc. Additive manufacturing processes may include, but are not limited to, 3D printing. As evident from the descriptions supra in respect of FIGS. 7 to 18 the FF-HEX are designed from the considerations of the recirculating fluid in the CPU/GPU loop, the fluid (typically air) being used to take heat away, modular design for simple scaling in heat extracted/performance without re-design, etc. and optimising the flow within at least the recirculating fluid in the CPU/GPU loop and optionally both fluid—EXUC interfaces. As evident from embodiments of the invention arrays of TIPs (and the application from an analytic thru the completed apparatus in operation of cell-based approaches using a plurality of cell designs and purposes) or “flow diverters” that direct the fluid to impinge on the EXUC surfaces, mix, etc. Designs may be implemented with single pass or double pass or multiple pass based upon the design of the top/bottom elements to which the EXUC stack interfaces.

Whilst square TIPs (in arrangements of cells comprising a plurality of TIPs) with an aspect ratio (height:width) of approximately 1:1 are employed within the FTEXEs/EXUCs supra in respect of FIGS. 1 to 18 as the means to increase the surface area the fluid interacts with in the FF-HEX/FTEXE designs where space is not or is as limited then different aspect ratios may be employed. Further, TIPs (even in a single cell) of multiple aspect ratios may be employed within a FF-HEX/FTEXE in different regions/“zones” or patterns according to the overall thermal transfer/geometry of the FF-HEX/FTEXE and characteristics of the fluid(s). As is thus presented the relationship of TIPs (and TIP cells) to each other is a key and unique element of the preferred embodiment of the Apparatus and the thermal energy transfer across a plurality of TIPs to the Thermal Transport Fluid is a central element of the invention.

Whilst square TIPs (and cells areas of various regular or irregular geometric shapes) are depicted it would be evident that rectangular, hexagonal, pentagonal, and other geometric/non-geometric/regular/irregular/random shapes may be employed establishing turbulent, abrupt transitional flow is an important element of the increased efficiency observed by the inventors. Further, the geometry of these TIPs may be non-uniform vertically, laterally and longitudinally relative to the flow such that, for example, triangular pins with a face approximately perpendicular to flow direction may be employed or alternatively conical TIPs or square TIPs that transition to a fructo-conical geometry. Similarly, they may be solid or hollow or partially hollow. Optionally, the material composition and/or material forming the projection may vary such that a HTCM or HTCC is employed closest to the source/sink of thermal energy but a lower cost material with lower thermal conduction is employed further away from the source/sink of thermal energy. Optionally, the geometries depicted in FIG. 6 with different “zones” may employ different materials, geometries, etc. within each zone. Optionally, the geometries within an EXUC may vary based upon the thermal profile(s) of the fluid(s) such that, for example, the TIP geometry may vary along the axis of one or both fluids. Accordingly, considering a radiator with hot first fluid being cooled by a cool second fluid the TIP geometries may vary along the flow direction of the first fluid and/or along the flow direction of the second fluid to provide, for example, increased uniformity of extraction from the first fluid and transfer to the second fluid.

The FF-HEX whilst depicted and described with respect to a single fan may exploit dual fans, one either side of the FF-HEX, or dual fans on one side, or multiple fans.

With respect to the radiator the selection of material may in many instances not be as critical as the material selection of the FTEXEs and accordingly, whilst HTCM and HTCC materials may be employed other materials may be selected including, but not limited to, aluminium, copper, copper-nickel, and stainless steel. Within embodiments of the invention FF-HEXs may be assembled and mechanically held together or they may employ mechanical means in association with one or other techniques such as welding, brazing, soldering, and adhesives/epoxies according to factors including, but not limited to, the materials being joined, operating temperature ranges, cost, and ease of manufacturing/assembly. Internally, surfaces exposed to the recirculating fluid may be surface treated to reduce corrosion, material aggregation, reaction with recirculating fluid etc. Such materials may include inert metals such as gold or alternatively plastics and/or fluropolymers such as Teflon™. Optionally, the internal surface may also be coated with a material to improve thermal conductivity to the FF-HEX element(s) such as metallic thin films of HTTMs such as gold, silver, and copper, for example, or thin films such as artificial diamond, graphene, and carbon nanotubes. Externally, the FF-HEX may be painted, plated, anodized, or conversion coated for example, to provide, for example, improved visual aesthetics, improved radiative heat loss, or corrosion resistance.

It would be evident to one skilled in the art that whilst the FF-HEX and FTEXEs have been described as separate elements connected via a fluidic circuit, e.g. piping and/or tubing, it would be evident that within other embodiments of the invention these may be part of the same mechanical assembly or mechanically linked through rigid fluidic coupling. Alternatively, they may be connected with flexible fluidic couplings. For example, the inlet/outlet of a FTEXE may be directly coupled to the FF-HEX via pump or pumps to provide fluid circulation within a single module compatible with a motherboard, server blade, rack unit, etc. Whilst within embodiments of the invention presented supra the EXUC elements were stacked such that they were stacked above one another it would be evident that within other embodiments of the invention EXUCs may be disposed linearly with respect to one another or in a variety of other configurations.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A fluidic thermal exchange element adapted to cool a heat generating component, comprising:
a thermal conductive element having a first surface that thermally contacts the heat generating component and a second surface having fins in a cell configuration;
a cover over the thermal conductive element that is fluidically sealed relative to the thermal conductive element to form a cavity, the cover having first and second fluid access points arranged relative to the fins such that cooled fluid flowing from the first access point to the second access point in the cavity interacts with the fins and acquires thermal energy therefrom to create heated fluid at the second access point; and
a modular radiator that receives the heated fluid from the second access point and cools the fluid to create the cooled fluid for recirculation to the first access point, said radiator comprising a plurality of fluid-fluid thermal coupling elements (FFTCEs), each FFTCE comprising first and second fluid thermal interface elements disposed in a frame, the radiator comprising a plurality of FFTCEs stacked upon each other between top and bottom plates to mechanically restrain the FFTCEs, wherein the top plate comprises a first fluid access port for accepting the heated fluid and directs the heated fluid to flow through access channels in the respective frames of the FFTCEs to provide heat exchange with the respective FFTCEs to provide the cooled fluid at a second fluid access port that is connected to said first fluid access point.

2. A fluidic thermal exchange element as in claim 1, wherein the fins comprise rows of slots that are aligned axially between said first and second fluidic access points.

3. A fluidic thermal exchange element as in claim 1, wherein the fins comprise a plurality of thermal interface projections disposed in one or more repetitive patterns whereby fluid flows through channels between the respective thermal interface projections from said first fluidic access point to said second fluidic access point.

4. A fluidic thermal exchange element as in claim 3, wherein the thermal interface projections are disposed in a staggered profile to provide increased fluid turbulence between said first and second fluidic access points.

5. A fluidic thermal exchange element as in claim 3, wherein the plurality of thermal interface projections are arranged to repeatedly separate and combine sub-flows of the fluid to locally change the velocity of the fluid and to induce mixing of the sub-flows.

6. A fluidic thermal exchange element as in claim 1, wherein a plurality of cells of fins are disposed on respective regions of the second surface of the thermal conductive element.

7. A fluidic thermal exchange element as in claim 6, wherein respective cells of fins employ different materials and/or geometries within each cell.

8. A fluidic thermal exchange element as in claim 1, wherein at least one of said FFTCEs comprises said second thermal interface element combined with said frame in a single piece having an open recessed portion including a slot that accepts the first thermal interface element.

9. A fluidic thermal exchange element as in claim 8, wherein said first thermal interface element has serpentine or linear folds.

10. A fluidic thermal exchange element as in claim 8, wherein the single piece has a plurality of pins on a surface thereof.

11. A fluidic thermal exchange element as in claim 8, wherein FFTCEs closer to the first fluid access port have a higher fin density or higher fluid flow therethrough compared to FFTCEs closer to the second access port.

12. A fluidic thermal exchange element as in claim 8, wherein a density of the first and second fluid thermal interface elements varies along a length of the radiator due to variations in thermal transfer arising from varying temperature of the fluid circulating within the radiator.

13. A fluidic thermal exchange element as in claim 1, wherein a plurality of stacks of said FFTCEs are arranged in an array.

14. A fluidic thermal exchange element as in claim 1, further comprising a fan disposed with respect to said radiator so as to move heat from said radiator.

15. A fluidic thermal exchange element as in claim 1, wherein a plurality of stacks of said FFTCEs are arranged in a three-dimensional configuration.

16. A fluidic thermal exchange element as in claim 15, further comprising a plurality of fans disposed on respective sides of said radiator so as to move heat from said radiator.

17. A fluidic thermal exchange element as in claim 1, wherein the radiator is immersed in a cooling fluid.

18. A fluidic thermal exchange element as in claim 1, wherein the FFTCEs are arranged in the radiator to provide a first fluid flow and a second fluid flow that are one of co-directional, contra-directional, or at a predetermined non-zero angle relative to one another.
